(19) United States
(12) Patent Application Publication
(10) Pub. No.: US 2025/0293661 A1
(43) Pub. Date: Sep. 18, 2025

(54) ACOUSTIC WAVE FILTER AND RADIO FREQUENCY MODULE

(71) Applicant: Murata Manufacturing Co., Ltd., Nagaokakyo-shi (JP)

(72) Inventor: Takuma KUROYANAGI, Nagaokakyo-shi (JP)

(73) Assignee: Murata Manufacturing Co., Ltd., Nagaokakyo-shi (JP)

(21) Appl. No.: 18/954,566

(22) Filed: Nov. 21, 2024

(30) Foreign Application Priority Data
Mar. 12, 2024 (JP) 2024-038007

(51) Int. Cl. H03H 9/02; H03H 9/00; H03H 9/05; H03H 9/10; H03H 9/56; H03H 9/64

(52) U.S. Cl. CPC H03H 9/02913; H03H 9/0009; H03H 9/0014; H03H 9/02086; H03H 9/0523; H03H 9/059; H03H 9/105; H03H 9/1092; H03H 9/568; H03H 9/6483

(57) ABSTRACT

An acoustic wave filter includes a piezoelectric substrate including a first main opposite to a second main surface. The first main surface includes two series-arm resonators disposed thereon. A cap substrate includes a third main surface facing the first main surface, and disposed to define a space between the first main surface and the third main surface. An external connection terminal is connected to the antenna connection terminal, and another external connection terminal is connected to an amplifier. A first wire that electrically connects the external connection terminal to one of the series-arm resonators, and a second wire that electrically connects the other external connection terminal to the other series-arm resonator are also included. A shield is disposed at the third main surface. The shield at least partially overlaps the second wire without overlapping the first wire in plan view.

### CROSS-REFERENCE TO RELATED APPLICATION

This application claims priority to Japanese application no. 2024-038007, filed Mar. 12, 2024, the entire contents of which are hereby incorporated by reference.

### BACKGROUND

### 1. Field

The present disclosure relates to an acoustic wave filter and a radio frequency module.

### 2. Description of the Related Art

In the related art there is described forming a hole in a ceiling portion of a shield case that shields a radio frequency filter. In this structure, capacitive coupling and/or inductive coupling between the radio frequency filter and the shield case is reduced, and deterioration of characteristics of the radio frequency filter is reduced.

### SUMMARY

The existing technology above, however, may fail to reduce deterioration of the attenuation characteristic of the shield while reducing deterioration of the transmission characteristic caused by coupling between the acoustic wave filter and other components.

Accordingly, it is an object of the present disclosure to provide an acoustic wave filter and a radio frequency module that can reduce deterioration of the transmission characteristic and the attenuation characteristic.

An acoustic wave filter according to an aspect of the present disclosure includes a piezoelectric substrate including a first main opposite to a second main surface. The first main surface includes two series-arm resonators disposed thereon. A cap substrate includes a third main surface facing the first main surface, and disposed to define a space between the first main surface and the third main surface. An external connection terminal is connected to the antenna connection terminal, and another external connection terminal is connected to an amplifier. A first wire that electrically connects the external connection terminal to one of the series-arm resonators, and a second wire that electrically connects the other external connection terminal to the other series-arm resonator are also included. A shield is disposed at the third main surface. The shield at least partially overlaps the second wire without overlapping the first wire in plan view.

In an acoustic wave filter according to the present disclosure, deterioration of the transmission characteristic and the attenuation characteristic can be reduced.

### BRIEF DESCRIPTION OF THE DRAWINGS

FIG. 1 is a circuit configuration diagram of a radio frequency module according to a first exemplary embodiment;

FIG. 2 is a plan view of the radio frequency module according to the first exemplary embodiment;

FIG. 3 is a cross-sectional view of the radio frequency module according to the first exemplary embodiment;

FIG. 4 is a cross-sectional view of an acoustic wave filter according to the first exemplary embodiment;

FIG. 5 is a cross-sectional view of the acoustic wave filter according to the first exemplary embodiment;

FIG. 6 is a cross-sectional view of the acoustic wave filter according to the first exemplary embodiment;

FIG. 7 is a Smith chart for illustrating the effect on parasitic capacitance caused by a shield;

FIG. 8 is a cross-sectional view of an acoustic wave filter according to a first modification example of the first exemplary embodiment;

FIG. 9 is a cross-sectional view of an acoustic wave filter according to a second modification example of the first exemplary embodiment;

FIG. 10 a cross-sectional view of the acoustic wave filter according to the second modification example of the first exemplary embodiment;

FIG. 11 is a partial cross-sectional view of the acoustic wave filter according to the second modification example of the first exemplary embodiment;

FIG. 12 is a circuit configuration diagram of a radio frequency module according to a second exemplary embodiment;

FIG. 13 is a cross-sectional view of a filter module according to the second exemplary embodiment;

FIG. 14 is a cross-sectional view of the filter module according to the second exemplary embodiment;

FIG. 15 is a circuit configuration diagram of a radio frequency module according to a third exemplary embodiment;

FIG. 16 is a cross-sectional view of a filter module according to the third exemplary embodiment; and

FIG. 17 is a cross-sectional view of a filter module according to the third exemplary embodiment.

### DETAILED DESCRIPTION

Hereafter, exemplary embodiments of the present disclosure are described in detail with reference to the drawings. The exemplary embodiments described below each illustrate a general or specific example. The numerical values, shapes, materials, components, and the arrangement of and connection between the components indicated in the exemplary embodiments below are mere examples, and are not intended to limit the present disclosure.

The drawings are schematic diagrams involving, as appropriate, accentuation, elimination, or adjustment in ratio to illustrate the present disclosure, and not necessarily precisely drawn. Thus, the drawings may differ from the actual ones in terms of shapes, positional relationships, and ratios. In each drawing, substantially the same components are denoted with the same reference sign, and redundant description may be omitted or simplified.

In each drawing described below, an x-axis and a y-axis are axes orthogonal to each other on a plane parallel to the main surface of a substrate. More specifically, when a substrate is rectangular in plan view, the x-axis is parallel to a first edge of a module substrate, and the y-axis is parallel to a second edge of the substrate orthogonal to the first edge. A z-axis is an axis perpendicular to the main surface of a substrate, a positive direction of the z-axis indicates upward, and a negative direction of the z-axis indicates downward.

In the description below, “being connected” includes, in addition to a case where components are directly connected to each other with a connection terminal and/or a wire conductor, a case where components are electrically connected to each other with another circuit element. The expression that “C is connected between A and B” indicates a case where one end of C is connected to A, another end of C is connected to B, and C is arranged in series on a path connecting A and B. The expression of “a path connecting A and B” indicates a path formed from a conductor that electrically connects A to B.

The expression of “a terminal” indicates a point where a conductor among components ends. When a conductor among components has sufficiently low impedance, a terminal is construed as any point on the conductor among the components or the entire conductor, instead of a single point.

The expression of “a filter pass band” is a portion of a frequency spectrum transmitted by a filter, and is defined as a frequency band in which output power does not attenuate more than or equal to 3 dB from the maximum output power. Thus, a high frequency end and a low frequency end of a pass band of a band pass filter are specified as a higher frequency and a lower frequency at two points where output power attenuates 3 dB from the maximum output power.

The expression of “a transmission band” indicates a frequency band used by a communication device for transmission. The expression of “a reception band” indicates a frequency band used by a communication device for reception. For example, in a frequency division duplex (FDD) band, different frequency bands (for example, an uplink band and a downlink band) are used as a transmission band and a reception band. For example, in a time division duplex (TDD) band, the same frequency band is used for the transmission band and the reception band.

The expression of “being simultaneously capable of communication” indicates a situation where multiple band signals can be simultaneously transmitted, received, or transmitted and received. A band combination that is simultaneously capable of communication is defined in advance by, for example, a standardization organization (for example, the 3rd generation partnership project (3GPP, registered trademark) and the Institute of Electrical and Electronics Engineers (IEEE). Examples of simultaneous communication include carrier aggregation (CA), E-UTRAN New Radio-Dual Connectivity (EN-DC), New Radio-Dual Connectivity (NR-DC), and New Radio E-UTRAN-Dual Connectivity (NE-DC).

The expression that “a component is disposed at a substrate” includes a case where a component is disposed on a main surface of a substrate and a case where a component is disposed in a substrate. The expression that “a component is disposed on a main surface of a substrate” includes, in addition to a case where a component is disposed in contact with the main surface of the substrate, a case where a component is disposed above the main surface without being in contact with the main surface (for example, a case where a component is laminated on another component disposed in contact with the main surface). The expression that “a component is disposed on a main surface of a substrate” may include a case where a component is disposed in a recess formed in the main surface. The expression that “a component is disposed in a substrate” includes, in addition to a case where a component is encapsulated in a module substrate, a case where the entirety of the component is disposed between both main surfaces of a substrate while a part of the component is left without being covered with the substrate, and a case where only a part of the component is disposed in the substrate.

“In plan view” indicates a view of an object projected on an xy plane along the z axis. “A overlaps B in plan view” indicates that an area A projected on the xy plane along the z axis overlaps an area B projected on the xy plane along the z axis.

The expression of “a shield covering a main surface of a substrate” indicates a state where, when a main surface of a substrate is viewed in a direction normal to the main surface, the main surface is blocked by a shield. Thus, the shield does not necessarily have to be in contact with the main surface.

Terms indicating the relations between components such as “parallel” and “perpendicular”, terms indicating the shapes of components such as “rectangular”, and numerical ranges do not only indicate the strict meanings, but also indicate substantially equivalent ranges, for example, allowable tolerances of about several percent.

### First Embodiment

A first exemplary embodiment is described. A radio frequency module 300 including an acoustic wave filter 100 according to the present exemplary embodiment is usable in a communication device used to provide wireless communications. For example, the radio frequency module 300 is usable in user equipment (UE) in a cellular network (also referred to as a mobile network) such as a mobile phone, a smartphone, a tablet computer, or a wearable device. In another example, the radio frequency module 300 is usable in a communication device used to provide wireless communications to an Internet of Things (IoT) sensor device, a medical/healthcare device, a vehicle, an unmanned aerial vehicle (UAV) (or a so-called drone), or an automated guided vehicle (AGV). In another example, the radio frequency module 300 is usable in a communication device used to provide wireless communications at a wireless access point or a wireless hot spot.

The circuit configuration of the radio frequency module 300 according to the present exemplary embodiment is described with reference to FIG. 1. FIG. 1 is a circuit configuration diagram of the radio frequency module 300 according to the present exemplary embodiment.

FIG. 1 illustrates an exemplary circuit configuration, and the radio frequency module 300 and the acoustic wave filter 100 may be implemented with any type of various circuit implementation and circuit technologies. Thus, the description of the radio frequency module 300 and the acoustic wave filter 100 provided below is not to be construed as being limiting.

### 1.1 Circuit Configuration of Radio Frequency Module 300

The radio frequency module 300 includes an acoustic wave filter 100, an inductor 200, and an antenna connection terminal 201. The circuit configuration of the acoustic wave filter 100 is described in detail later.

The antenna connection terminal 201 is an external connection terminal of the radio frequency module 300. The antenna connection terminal 201 is connected to an antenna (not illustrated) outside the radio frequency module 300, and connected to the acoustic wave filter 100 in the radio frequency module 300.

The acoustic wave filter 100 is a band pass filter having a pass band including a reception band of a band A. The acoustic wave filter 100 may be a band pass filter having a pass band including a transmission band of the band A. The acoustic wave filter 100 is not limited to a band pass filter. A surface acoustic wave (SAW) filter or a bulk acoustic wave (BAW) filter may be used as an example of the acoustic wave filter 100.

The band A is an example of a first band, which is a frequency band for a communication system built with a radio access technology (RAT). The band A is defined in advance by, for example, a standardization organization (such as 3GPP or IEEE). Examples of a communication system include the 5th generation new radio (5GNR) system, the long term evolution (LTE) system, and the wireless local area network (WLAN) system.

The inductor 200 is connected between a ground and a path connecting the antenna connection terminal 201 and the acoustic wave filter 100. The inductor 200 forms, for example, an impedance matching circuit. The circuit configuration of the impedance matching circuit is not limited to the circuit configuration in FIG. 1. For example, in addition to the inductor 200 or instead of the inductor 200, the impedance matching circuit may include an inductor and/or a capacitor connected between the antenna connection terminal 201 and the acoustic wave filter 100, or include a capacitor connected between a ground and a path connecting the antenna connection terminal 201 and the acoustic wave filter 100.

The radio frequency module 300 may include a power amplifier and/or a low-noise amplifier, or include multiple acoustic wave filters 100.

### 1.2 Circuit Configuration of Acoustic Wave Filter 100

The circuit configuration of the acoustic wave filter 100 is described now with reference to FIG. 1. The acoustic wave filter 100 includes series-arm resonators 101, 102, and 103, parallel-arm resonators 111, 112, and 113, and external connection terminals 121, 122, and 123.

The external connection terminal 121 is an example of a first external connection terminal. The external connection terminal 121 is connected to the antenna connection terminal 201 outside the acoustic wave filter 100, and connected to the series-arm resonator 101 in the acoustic wave filter 100.

The external connection terminal 122 is an example of a second external connection terminal. The external connection terminal 122 is connected to a power amplifier (not illustrated) and/or a low-noise amplifier (not illustrated) outside the acoustic wave filter 100, and connected to the series-arm resonator 103 in the acoustic wave filter 100.

The external connection terminals 123 are connected to the ground outside the acoustic wave filter 100, and connected to the parallel-arm resonators 111 to 113 in the acoustic wave filter 100.

The series-arm resonators 101 to 103 are connected in series between the external connection terminals 121 and 122. More specifically, the series-arm resonator 101 is an example of a first series-arm resonator, and connected between the external connection terminal 121 and the series-arm resonator 102. The series-arm resonator 102 is connected between the series-arm resonators 101 and 103. The series-arm resonator 103 is an example of a second series-arm resonator, and connected between the series-arm resonator 102 and the external connection terminal 122.

The parallel-arm resonators 111 to 113 are connected in parallel to one another between the ground and a path connecting the external connection terminals 121 and 122. More specifically, the parallel-arm resonator 111 is connected between the path connecting the series-arm resonators 101 and 102 and a corresponding one of the external connection terminals 123. The parallel-arm resonator 112 is connected between the path connecting the series-arm resonators 102 and 103 and a corresponding one of the external connection terminals 123. The parallel-arm resonator 113 is connected between the path connecting the series-arm resonator 103 and the external connection terminal 122 and a corresponding one of the external connection terminals 123.

The number of series-arm resonators and the number of parallel-arm resonators included in the acoustic wave filter 100 are not limited to the numbers of resonators illustrated in FIG. 1. For example, the acoustic wave filter 100 may include one series-arm resonator and one parallel-arm resonator. More specifically, in the acoustic wave filter 100, the first series-arm resonator and the second series-arm resonator may be the same series-arm resonator.

### 1.3 Implementation Example of Radio Frequency Module 300

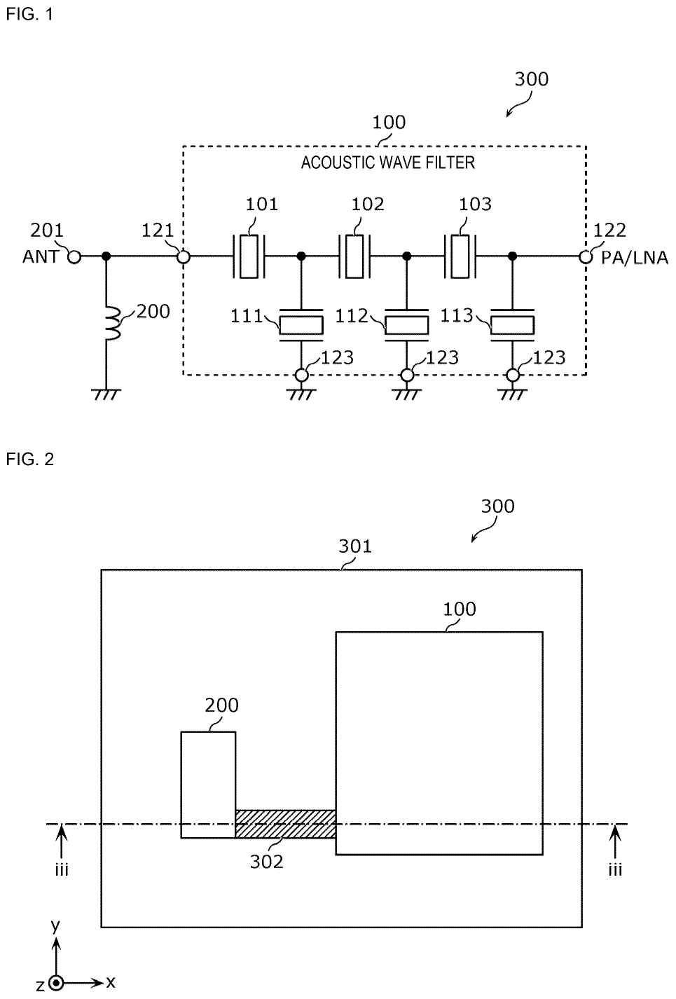

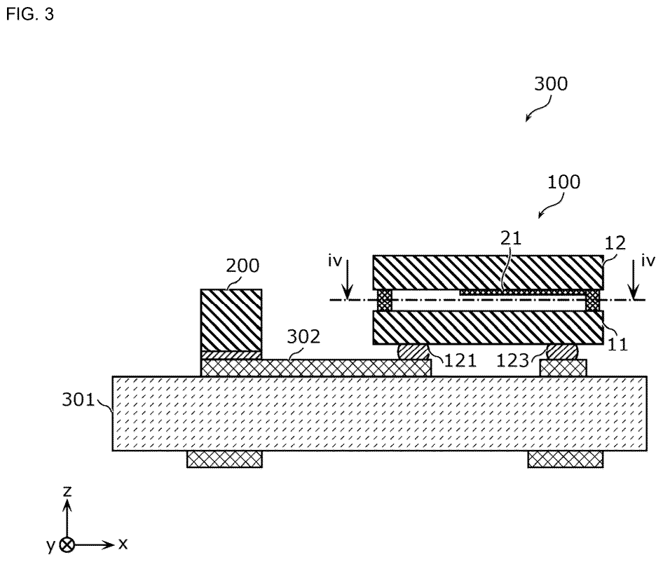

An implementation example of the radio frequency module 300 is described now with reference to FIG. 2 and FIG. 3. FIG. 2 is a plan view of the radio frequency module 300 according to the present exemplary embodiment. FIG. 3 is a cross-sectional view of the radio frequency module 300 according to the present exemplary embodiment. The cross section of the radio frequency module 300 in FIG. 3 is a cross section taken along line iii-iii in FIG. 2.

FIG. 2 and FIG. 3 are exemplary drawings. The radio frequency module 300 may be implemented with any type of various circuit implementation and circuit technologies. Thus, the description of the radio frequency module 300 provided below is not to be construed as being limiting.

The radio frequency module 300 includes a module substrate 301, the acoustic wave filter 100, and the inductor 200. The acoustic wave filter 100 and the inductor 200 are disposed on the main surface of the module substrate 301.

The module substrate 301 may be, for example, a low temperature co-fired ceramics (LTCC) substrate or a high temperature co-fired ceramics (HTCC) substrate having a laminated structure of multiple dielectric layers, a substrate with built-in components, a substrate having a redistribution layer (RDL), or a printed circuit board, but is not limited to these.

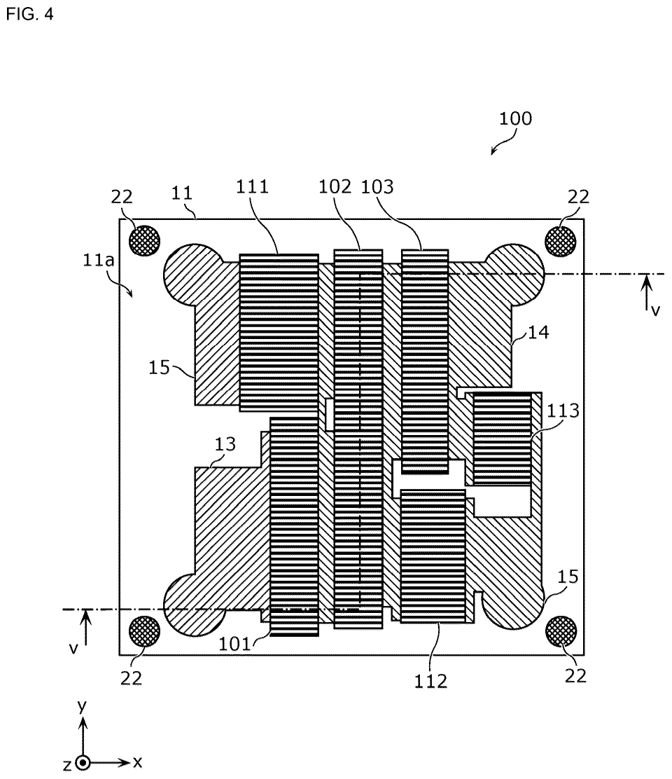

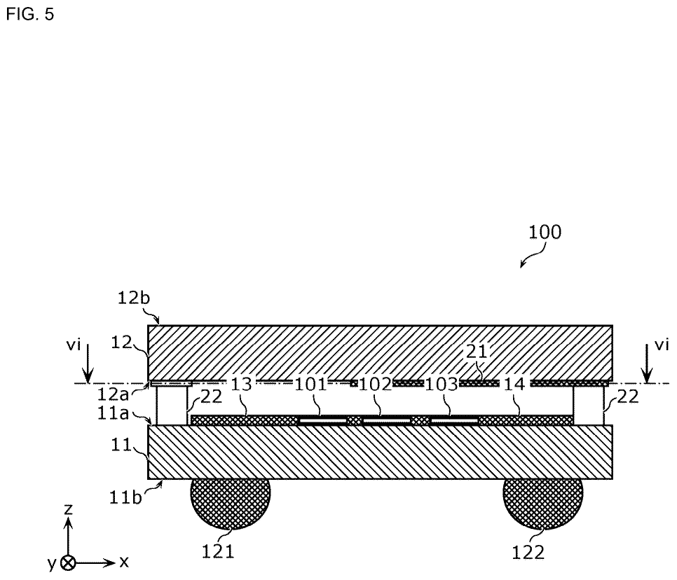

The acoustic wave filter 100 includes a piezoelectric substrate 11, a cap substrate 12, a shield 21, and external connection terminals 121 to 123. The external connection terminal 121 is electrically connected to the inductor 200 through a wire 302 on the module substrate 301. The acoustic wave filter 100 is described in detail later with reference to FIG. 4 to FIG. 6.

The inductor 200 is implemented as a chip inductor. A chip inductor indicates a surface mount device (SMD) forming an inductor. The inductor 200 may be implemented in a form other than a chip inductor. For example, the inductor 200 may be implemented by a wire pattern disposed at the module substrate 301.

### 1.4 Implementation Example of Acoustic Wave Filter 100

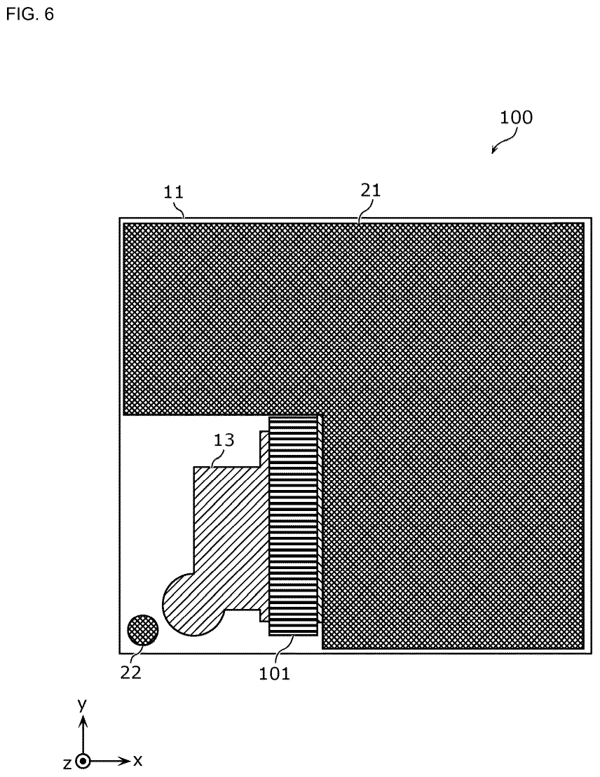

An implementation example of the acoustic wave filter 100 is described now with reference to FIG. 4 to FIG. 6. FIG. 4 to FIG. 6 are cross-sectional views of the acoustic wave filter 100 according to the present exemplary embodiment. The cross section of the acoustic wave filter 100 in FIG. 4 is a cross section taken along line iv-iv in FIG. 3. The cross section of the acoustic wave filter 100 in FIG. 5 is a cross section taken along line v-v in FIG. 4. The cross section of the acoustic wave filter 100 in FIG. 6 is a cross section taken along line vi-vi in FIG. 5.

FIG. 4 to FIG. 6 are exemplary diagrams, and the acoustic wave filter 100 may be implemented with any type of various circuit implementation and circuit technologies. Thus, the description of the acoustic wave filter 100 provided below is not to be construed as being limiting.

The piezoelectric substrate 11 is an example of a first substrate, and has main surfaces 11a and 11b opposite to each other. The main surface 11a is an example of a first main surface, and the main surface 11b is an example of a second main surface. The piezoelectric substrate 11 is formed from, for example, piezoelectric ceramics or a piezoelectric single crystal of lithium tantalate (LiTaO₃), lithium niobate (LiNbO₃), aluminium nitride (AlN), or zinc oxide (ZnO). The material of the piezoelectric substrate 11 is not limited to any of these.

The series-arm resonators 101 to 103 and the parallel-arm resonators 111 to 113 are disposed on the main surface 11a of the piezoelectric substrate 11. The series-arm resonators 101 to 103 and the parallel-arm resonators 111 to 113 are, for example, inter digital transducer (IDT) electrodes disposed on the main surface 11a of the piezoelectric substrate 11. The IDT electrodes can generate and detect surface acoustic waves.

Wires 13, 14, and 15 are also disposed at the main surface 11a of the piezoelectric substrate 11. The wire 13 electrically connects the series-arm resonator 101 to the external connection terminal 121 disposed at the main surface 11b. The wire 14 electrically connects the series-arm resonator 103 to the external connection terminal 122 disposed at the main surface 11b. The wire 15 electrically connects the parallel-arm resonators 111 to 113 to the external connection terminals 123 disposed at the main surface 11b. The wires 13 to 15 may include busbar electrodes of the IDT electrodes.

The cap substrate 12 is an example of a second substrate, and has main surfaces 12a and 12b. The main surface 12a is an example of a third main surface, and faces the main surface 11a of the piezoelectric substrate 11. The main surface 12b is an example of a fourth main surface. The cap substrate 12 is disposed to define a space between the main surface 11a and the main surface 12b, and supported by supporters 22. The shield 21 is disposed at the main surface 12a of the cap substrate 12.

The shield 21 covers a part of the main surface 12a of the cap substrate 12. The shield 21 is, for example, a metal film formed by sputtering, and is connected to the ground. The shield 21 can reduce capacitive coupling (electric field coupling) and/or inductive coupling (magnetic field coupling) between components in the acoustic wave filter 100 and components outside the acoustic wave filter 100.

As illustrated in FIG. 4 and FIG. 6, the shield 21 overlaps the wire 14 and the series-arm resonator 103 in plan view without overlapping the wire 13 and the series-arm resonator 101. The shield 21 may overlap only the wire 14 in plan view without overlapping the series-arm resonator 103. The shield 21 may overlap the series-arm resonator 101 in plan view.

The external connection terminals 121 to 123 are disposed at the main surface 11b of the piezoelectric substrate 11. The external connection terminals 121 to 123 are electrically connected to a ground terminal and an input/output terminal of the module substrate 301. Copper electrodes or solder electrodes are used as examples of the external connection terminals 121 to 123.

### 1.5 Effects on Parasitic Capacitance Caused by Shield 21

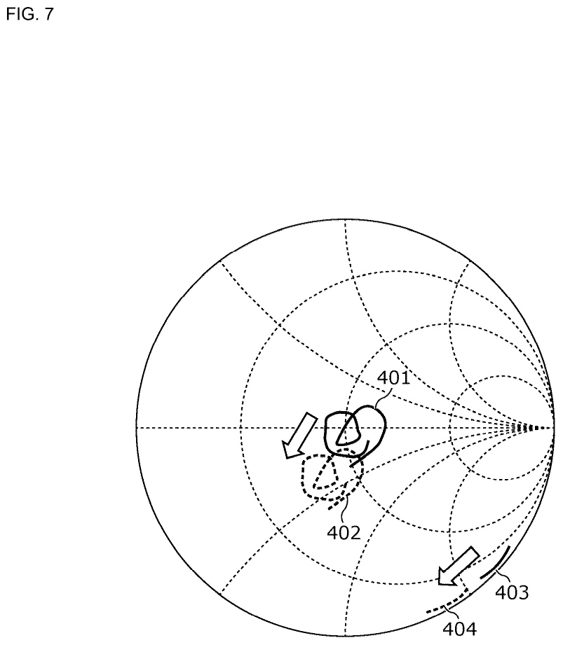

The effects on parasitic capacitance caused by the shield 21 are described with reference to FIG. 7. FIG. 7 is a Smith chart for illustrating the effects on parasitic capacitance caused by the shield 21. In FIG. 7, an impedance 401 indicates impedance of a reception band of the band A (a pass band of the acoustic wave filter 100) when the acoustic wave filter 100 including no shield 21 is viewed from the antenna connection terminal 201. An impedance 402 indicates impedance of a reception band of the band A when the acoustic wave filter 100 including the shield 21 is viewed from the antenna connection terminal 201. An impedance 403 indicates impedance of a reception band of a band B simultaneously capable of communicating with the band A when the acoustic wave filter 100 including no shield 21 is viewed from the antenna connection terminal 201. An impedance 404 indicates impedance of a reception band of the band B when the acoustic wave filter 100 including the shield 21 is viewed from the antenna connection terminal 201.

The acoustic wave filter 100 including the shield 21 causes parasitic capacitance between the wire and the resonator and the shield, and thus, the impedance 401 shifts to the impedance 402. For impedance matching of the impedance 402, the inductance value of the inductor 200 is to be reduced, and thus a loss in the pass band increases.

In the present exemplary embodiment, a case where the inductor 200 is connected between the ground and the path connecting the antenna connection terminal 201 and the acoustic wave filter 100 is described, but the same applies to the case where the inductor 200 is connected between the antenna connection terminal 201 and the acoustic wave filter 100. More specifically, with an increase of parasitic capacitance in the acoustic wave filter 100, the inductance value of the inductor 200 is to be increased, and a loss in the pass band increases.

In addition, when the impedance 403 shifts to the impedance 404, a signal of the band B simultaneously capable of communicating with the band A is more likely to leak to the path of the acoustic wave filter 100, and thus, isolation in the band B deteriorates. Thus, from a view point of parasitic capacitance, an area in the acoustic wave filter 100 covered with the shield 21 is preferably smaller.

However, when the acoustic wave filter 100 includes no shield 21, capacitive coupling and/or inductive coupling may occur between, for example, the inductor 200 and the acoustic wave filter 100, and the attenuation characteristic of the acoustic wave filter 100 deteriorates. Thus, from a view point of capacitive coupling and/or inductive coupling, an area in the acoustic wave filter 100 covered with the shield 21 is preferably larger. 1.6 Summarization

As described above, the acoustic wave filter 100 according to the present exemplary embodiment includes the piezoelectric substrate 11 having the main surfaces 11a and 11b opposite to each other, and having the main surface 11a at which the series-arm resonators 101 and 103 are disposed, the cap substrate 12 having the main surface 12a facing the main surface 11a of the piezoelectric substrate 11, and disposed to define a space between the main surface 11a and the main surface 12a, the external connection terminal 121 connected to the antenna connection terminal 201, the external connection terminal 122 connected to an amplifier, the wire 13 that electrically connects the external connection terminal 121 to the series-arm resonator 101, the wire 14 that electrically connects the external connection terminal 122 to the series-arm resonator 103, and the shield 21 disposed at the main surface 12a, wherein the shield 21 at least partially overlaps the wire 14 without overlapping the wire 13 in plan view.

In this structure, the shield 21 at least partially overlaps the wire 14, and thus, coupling between another component (for example, the inductor 200) and the wire 14 can be reduced, and deterioration of an attenuation characteristic can be reduced. Particularly, when the inductor 200 and the wire 14 are coupled, a large part of the acoustic wave filter 100 is skipped, and attenuation largely decreases. Thus, deterioration of the attenuation characteristic is highly effectively reduced by the shield 21 overlapping the wire 14. In contrast, the shield 21 does not overlap the wire 13, and thus, parasitic capacitance that occurs between the shield 21 and the wire 13 can be reduced. Thus, the decrease of the inductance value of the inductor 200 for impedance matching can be reduced, and an increase of a loss can be reduced. Regardless of when the inductor 200 and the wire 13 are coupled, attenuation can be obtained by a resonator between the wire 13 and the external connection terminal 122, and thus the effect on deterioration of the attenuation characteristic is small. As described above, in the acoustic wave filter 100, when the shield 21 is effectively disposed, deterioration of the transmission characteristic and the attenuation characteristic can be reduced.

For example, in the acoustic wave filter 100 according to the present exemplary embodiment, the shield 21 does not have to overlap the series-arm resonator 101 in plan view.

In this structure, the shield 21 does not overlap the series-arm resonator 101. Thus, parasitic capacitance that occurs between the shield 21 and the series-arm resonator 101 can be further reduced. This structure can thus reduce a decrease of the inductance value of the inductor 200 for impedance matching, and can reduce an increase of a loss. Regardless of when the inductor 200 and the series-arm resonator 101 are coupled, attenuation can be obtained to some extent by a resonator between the series-arm resonator 101 and the external connection terminal 122, and the effect on deterioration of the attenuation characteristic is low.

For example, in the acoustic wave filter 100 according to the present exemplary embodiment, the shield 21 may at least partially overlap the series-arm resonator 103 in plan view.

In this structure, the shield 21 at least partially overlaps the series-arm resonator 103. This structure can thus reduce coupling between another component (for example, the inductor 200) and the series-arm resonator 103, and can reduce deterioration of the attenuation characteristic. Particularly, when the inductor 200 and the series-arm resonator 103 are coupled, a large part of the acoustic wave filter 100 is skipped, and attenuation largely decreases. Thus, deterioration of the attenuation characteristic is highly effectively reduced by the shield 21 overlapping the series-arm resonator 103.

For example, the acoustic wave filter 100 according to the present exemplary embodiment may be a surface acoustic wave filter.

In this structure, the above effects can be obtained with the surface acoustic wave filter.

For example, the acoustic wave filter 100 according to the present exemplary embodiment may include a pass band including a reception band of the band A, and the amplifier may be a low-noise amplifier.

In this structure, the acoustic wave filter 100 is usable as a transmission filter.

For example, the acoustic wave filter 100 according to the present exemplary embodiment may include a pass band including a transmission band of the band A, and the amplifier may be a power amplifier.

In this structure, the acoustic wave filter 100 is usable as a reception filter.

The radio frequency module 300 according to the present exemplary embodiment includes the module substrate 301, the acoustic wave filter 100 disposed at the module substrate 301, and the inductor 200 disposed at the module substrate 301 and electrically connected to the external connection terminal 121 of the acoustic wave filter 100.

In this structure, in the radio frequency module 300 in which the inductor 200 is connected to the acoustic wave filter 100, the effects of the acoustic wave filter 100 can be implemented.

### First Modification Example of First Embodiment

A first modification example of the first exemplary embodiment is described now. The present modification example mainly differs from the first exemplary embodiment in terms of the shape of the shield. Hereafter, the present modification example is described with reference to the drawings mainly on the point different from the first exemplary embodiment.

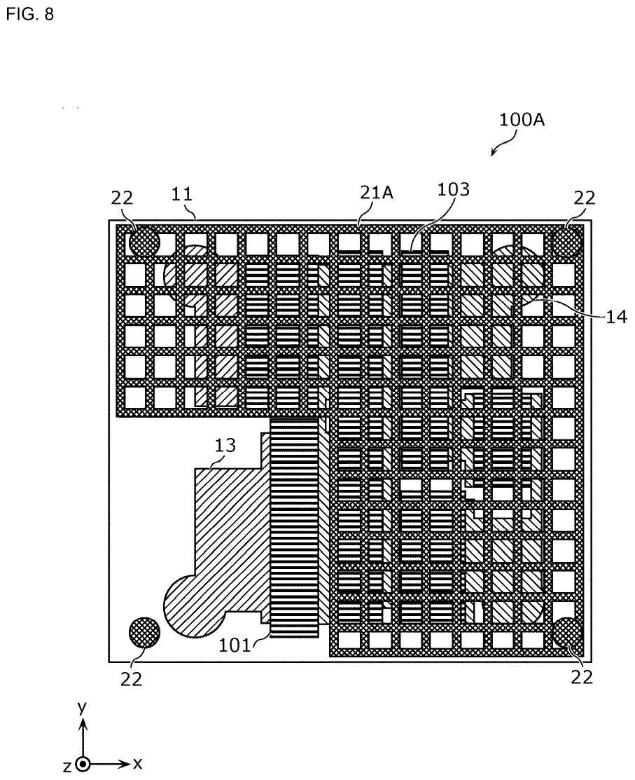

FIG. 8 is a cross-sectional view of an acoustic wave filter 100A according to the present modification example. FIG. 8 corresponds to a cross-sectional view in FIG. 6 according to the first exemplary embodiment. FIG. 8 illustrates an exemplary diagram, and the acoustic wave filter 100A may be implemented with any type of various circuit implementation and circuit technologies. Thus, the description of the acoustic wave filter 100A provided below is not to be construed as being limiting.

The acoustic wave filter 100A includes a shield 21A instead of the shield 21. The shield 21A has a mesh shape in plan view. The shield 21A partially overlaps the wire 14 and the series-arm resonator 103 in plan view without overlapping the wire 13 and the series-arm resonator 101. The shield 21A does not have to overlap the series-arm resonator 103 in plan view. The shield 21A may overlap the series-arm resonator 101 in plan view.

As described above, in the acoustic wave filter 100A according to the present modification example, the shield 21A may have a mesh shape in plan view.

In this structure, the shield 21A having a mesh shape partially overlaps the wire 14, and thus, coupling between another component (for example, the inductor 200) and the wire 14 can be reduced, and thus, parasitic capacitance that occurs between the shield 21A and the wire 13 can be reduced.

### Second Modification Example of First Embodiment

A second modification example of the first exemplary embodiment is now described. The present modification example mainly differs from the first exemplary embodiment in that the acoustic wave filter is a BAW filter. Hereafter, the present modification example is described with reference to the drawings mainly on the point different from the first exemplary embodiment.

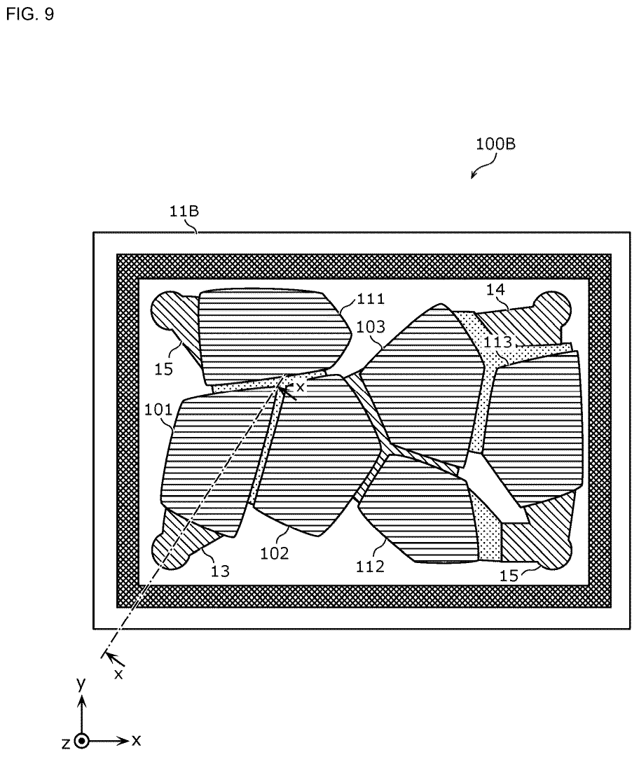

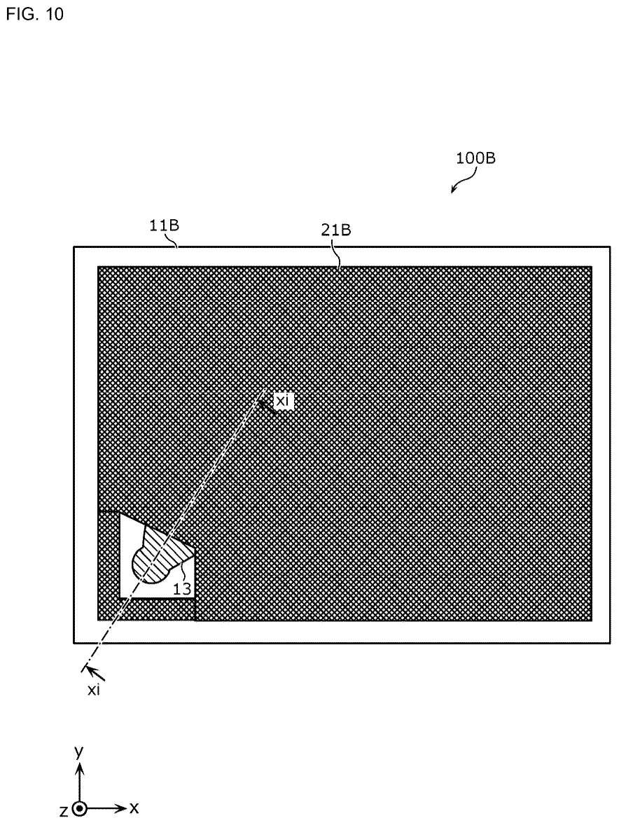

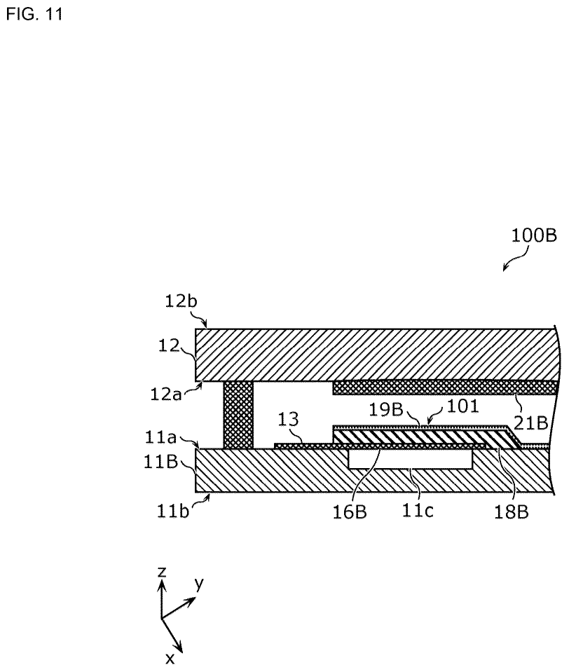

FIG. 9 and FIG. 10 are cross-sectional views of an acoustic wave filter 100B according to the present modification example. FIG. 9 corresponds to a cross-sectional view in FIG. 4 according to the first exemplary embodiment, and FIG. 10 corresponds to a cross-sectional view in FIG. 6 according to the first exemplary embodiment. FIG. 11 is a partial cross-sectional view of the acoustic wave filter 100B according to the present modification example. The cross section of the acoustic wave filter 100B in FIG. 10 is a cross section taken along line x-x in FIG. 9, and the cross section of the acoustic wave filter 100B in FIG. 11 is a cross section taken along line xi-xi in FIG. 10.

FIG. 9 to FIG. 11 are exemplary diagrams, and the acoustic wave filter 100B may be implemented with any type of various circuit implementation and circuit technologies. Thus, the description of the acoustic wave filter 100B provided below is not to be construed as being limiting.

The acoustic wave filter 100B includes a support substrate 11B. The series-arm resonators 101 to 103 and the parallel-arm resonators 111 to 113 are disposed at the support substrate 11B. The series-arm resonator 101 includes a lower electrode 16B, a piezoelectric member 18B, and an upper electrode 19B disposed above a recess 11c in the support substrate 11B. The piezoelectric member 18B is disposed between the lower electrode 16B and the upper electrode 19B. The lower electrode 16B is connected to the wire 13.

A shield 21B differs from the shield 21 according to the first exemplary embodiment in that the shield 21B at least partially overlaps the series-arm resonator 101 in plan view.

As described above, the acoustic wave filter 100B according to the present modification example may be a bulk acoustic wave filter.

In this structure, the same effects as those obtained by the acoustic wave filter 100 according to the first exemplary embodiment can be obtained with a bulk acoustic wave filter (the acoustic wave filter 100B).

For example, in the acoustic wave filter 100B according to the present modification example, the series-arm resonator 101 may include the lower electrode 16B, the upper electrode 19B, and the piezoelectric member 18B disposed between the lower electrode 16B and the upper electrode 19B, and the wire 13 may be connected to the lower electrode 16B.

In this structure, the wire 13 is connected to the lower electrode 16B. Thus, parasitic capacitance that occurs between the wire 13 and the shield 21B disposed above the series-arm resonator 101 can be further reduced than in the case where the wire 13 is connected to the upper electrode 19B.

### Second Embodiment

A second exemplary embodiment is described now. The present exemplary embodiment mainly differs from the first exemplary embodiment in that an acoustic wave filter is divided into pieces and mounted on different substrates. Hereafter, the present exemplary embodiment is described with reference to the drawings mainly on the point different from the first exemplary embodiment.

### 2.1 Circuit Configuration of Radio Frequency Module 300C and Acoustic Wave Filter 100C

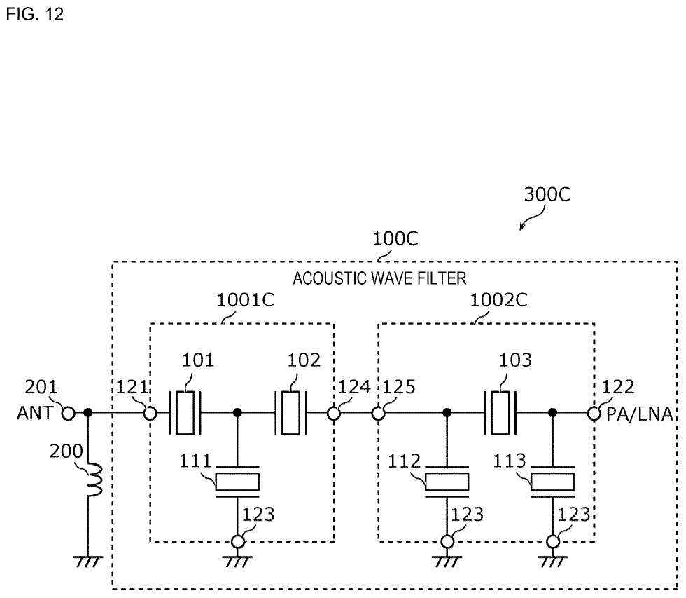

FIG. 12 is a circuit configuration diagram of a radio frequency module 300C according to the present exemplary embodiment. FIG. 12 illustrates an exemplary circuit configuration, and the radio frequency module 300C and an acoustic wave filter 100C may be implemented with any type of various circuit implementation and circuit technologies. Thus, the description of the radio frequency module 300C and the acoustic wave filter 100C provided below is not to be construed as being limiting.

The radio frequency module 300C includes the acoustic wave filter 100C, the inductor 200, and the antenna connection terminal 201.

As in the case of the acoustic wave filter 100 according to the first exemplary embodiment, the acoustic wave filter 100C is a band pass filter having a pass band including a reception band of a band A. The acoustic wave filter 100C includes series-arm resonators 101, 102, and 103, parallel-arm resonators 111, 112, and 113, and external connection terminals 121, 122, and 123. The acoustic wave filter 100C is divided into two filter modules 1001C and 1002C and implemented.

The filter module 1001C includes the series-arm resonators 101 and 102, the parallel-arm resonator 111, and external connection terminals 121, 123, and 124.

The external connection terminal 124 is an example of a third external connection terminal, is connected to an external connection terminal 125 of the filter module 1002C outside the filter module 1001C, and is connected to the series-arm resonator 102 in the filter module 1001C.

The filter module 1002C includes the series-arm resonator 103, the parallel-arm resonators 112 and 113, and the external connection terminals 122, 123, and 125.

The external connection terminal 125 is an example of a fourth external connection terminal, is connected to the external connection terminal 124 of the filter module 1001C outside the filter module 1002C, and is connected to the series-arm resonator 103 in the filter module 1002C.

### 2.2 Implementation Example of Acoustic Wave Filter 100C

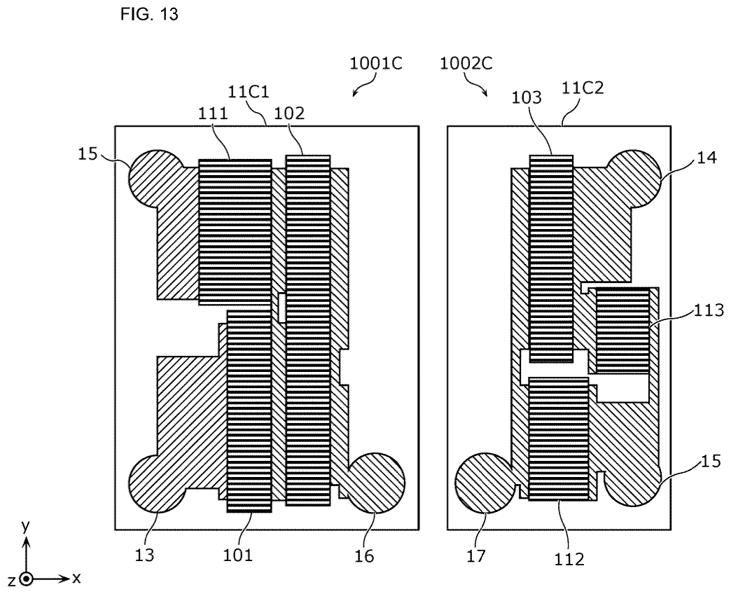

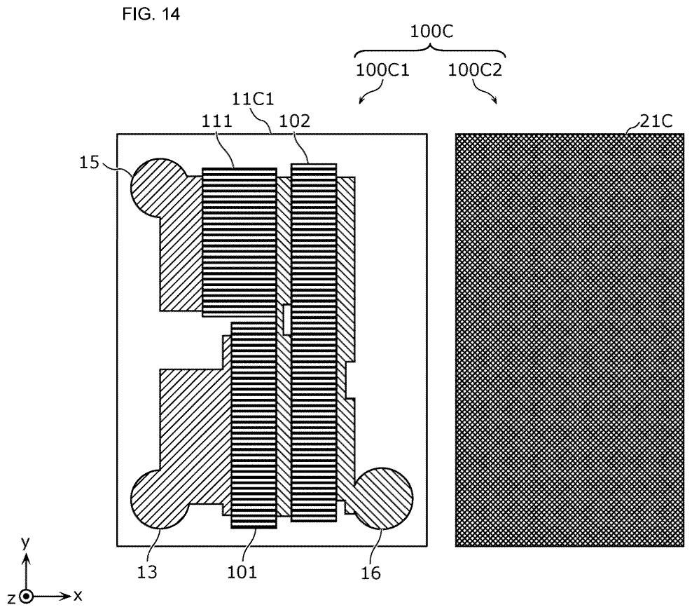

An implementation example of the acoustic wave filter 100C is described now with reference to FIG. 13. FIG. 13 and FIG. 14 are cross-sectional views of the filter modules 1001C and 1002C according to the present exemplary embodiment. FIG. 13 and FIG. 14 are exemplary diagrams, and the acoustic wave filter 100C may be implemented with any type of various circuit implementation and circuit technologies. Thus, the description of the filter modules 1001C and 1002C provided below is not to be construed as being limiting.

The filter module 1001C includes a piezoelectric substrate 11C1 serving as an example of a first substrate. The series-arm resonators 101 and 102, the parallel-arm resonator 111, and wires 13, 15, and 16 are disposed at the piezoelectric substrate 11C1. The wire 16 electrically connects the series-arm resonator 102 to the external connection terminal 124. The piezoelectric substrate 11C1 is not covered with a shield. In other words, the series-arm resonators 101 and 102, the parallel-arm resonator 111, and the wires 13, 15, and 16 do not overlap the shield in plan view.

The filter module 1002C includes a piezoelectric substrate 11C2 serving as a second substrate. The series-arm resonator 103, the parallel-arm resonators 112 and 113, and wires 14, 15, and 17 are disposed at the piezoelectric substrate 11C2. The wire 17 electrically connects the series-arm resonator 103 to the external connection terminal 125. The piezoelectric substrate 11C2 is covered with a shield 21C. In other words, the series-arm resonator 103, the series-arm resonators 112 and 113, and the wires 14, 15, and 17 overlap the shield 21C in plan view. In the present exemplary embodiment, the entirety of the piezoelectric substrate 11C2 is covered with the shield 21C. Instead, a part of the piezoelectric substrate 11C2 may be left without being covered with the shield 21C.

The number of series-arm resonators and the number of parallel-arm resonators included in each of the filter modules 1001C and 1002C are not limited to the numbers of resonators illustrated in FIG. 13.

### Third Embodiment

A third exemplary embodiment is described now. The present exemplary embodiment mainly differs from the second exemplary embodiment in that a radio frequency module includes two acoustic wave filters having different pass bands. Hereafter, the present exemplary embodiment is described with reference to the drawings mainly on the point different from the second exemplary embodiment.

### 3.1 Circuit Configuration of Radio Frequency Module 300D and Acoustic Wave Filters 100C and 100D

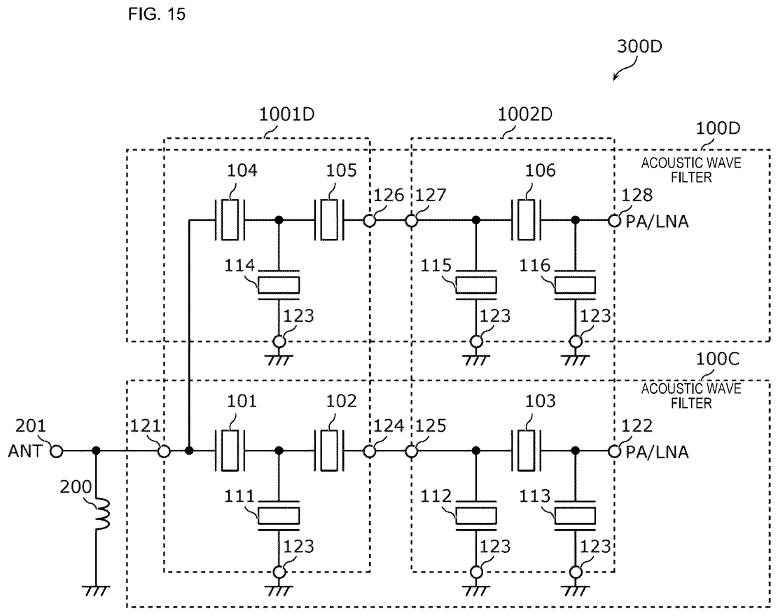

FIG. 15 is a circuit configuration diagram of a radio frequency module 300D according to the present exemplary embodiment. FIG. 15 illustrates an exemplary circuit configuration, and the radio frequency module 300D and acoustic wave filters 100C and 100D may be implemented with any type of various circuit implementation and circuit technologies. Thus, the description of the radio frequency module 300D and the acoustic wave filters 100C and 100D provided below is not to be construed as being limiting.

The radio frequency module 300D includes the acoustic wave filters 100C and 100D, the inductor 200, and the antenna connection terminal 201.

The acoustic wave filter 100D is a band pass filter having a pass band including a reception band of the band B simultaneously capable of communicating with the band A. The acoustic wave filter 100D may be a band pass filter having a pass band including a transmission band of the band B. The acoustic wave filter 100D is not limited to a band pass filter. The band B is an example of a second band, a frequency band for a communication system built with a RAT as in the band A, and defined in advance by, for example, a standardization organization.

The acoustic wave filter 100D includes series-arm resonators 104, 105, and 106, parallel-arm resonators 114, 115, and 116, and external connection terminals 123 and 128.

The external connection terminal 128 is connected to a power amplifier (not illustrated) and/or a low-noise amplifier (not illustrated) outside the acoustic wave filter 100D, and connected to the series-arm resonator 106 in the acoustic wave filter 100D.

The series-arm resonators 104 to 106 are connected in series between the external connection terminals 121 and 128. More specifically, the series-arm resonator 104 is connected between the external connection terminal 121 and the series-arm resonator 105. The series-arm resonator 105 is connected between the series-arm resonators 104 and 106. The series-arm resonator 106 is connected between the series-arm resonator 105 and the external connection terminal 128.

The parallel-arm resonators 114 to 116 are connected in parallel between the ground and a path connecting the external connection terminals 121 and 128. More specifically, the parallel-arm resonator 114 is connected between the path connecting the series-arm resonators 104 and 105 and a corresponding one of the external connection terminals 123. The parallel-arm resonator 115 is connected between the path connecting the series-arm resonators 105 and 106 and a corresponding one of the external connection terminals 123. The parallel-arm resonator 116 is connected between the path connecting the series-arm resonator 106 and the external connection terminal 128 and a corresponding one of the external connection terminals 123.

A part of the acoustic wave filter 100C and a part of the acoustic wave filter 100D are mounted on a filter module 1001D, and another part of the acoustic wave filter 100C and another part of the acoustic wave filter 100D are mounted on a filter module 1002D.

The filter module 1001D includes the series-arm resonators 101, 102, 104, and 105, the parallel-arm resonators 111 and 114, and external connection terminals 121, 123, 124, and 126.

The external connection terminal 126 is connected to an external connection terminal 127 of the filter module 1002D outside the filter module 1001D, and connected to the series-arm resonator 105 in the filter module 1001D.

The filter module 1002D includes the series-arm resonators 103 and 106, the parallel-arm resonators 112, 113, 115, and 116, and the external connection terminals 122, 123, 125, 127, and 128.

The external connection terminal 127 is connected to the external connection terminal 126 of the filter module 1001D outside the filter module 1002D, and connected to the series-arm resonator 106 in the filter module 1002D.

The number of series-arm resonators and the number of parallel-arm resonators included in each of the acoustic wave filters 100C and 100D are not limited to the numbers of resonators illustrated in FIG. 15.

### 3.2 Implementation Examples of Acoustic Wave Filters 100C and 100D

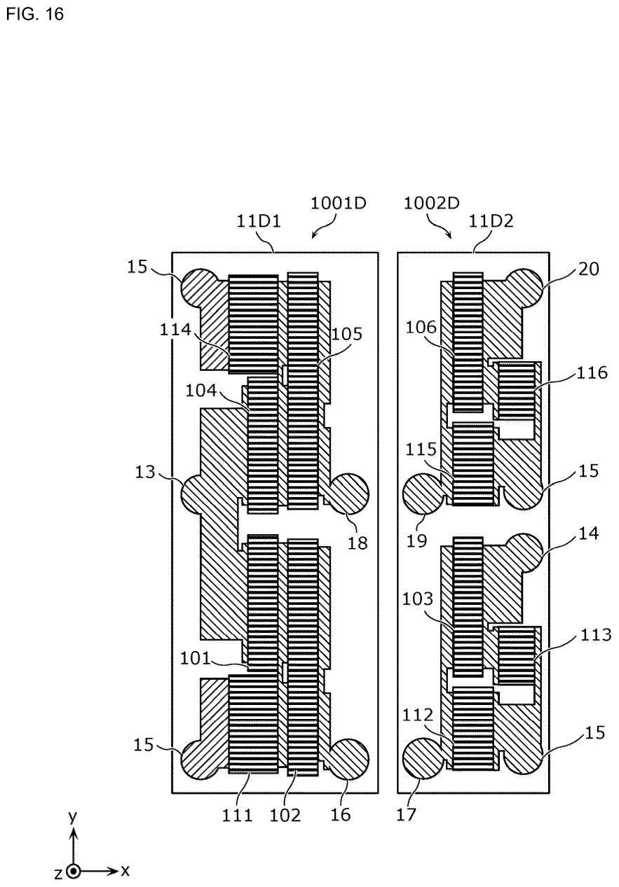

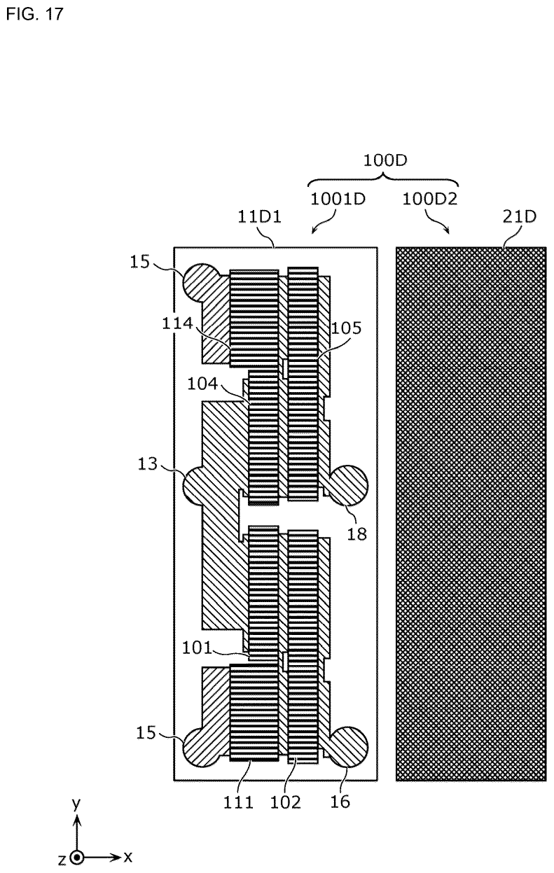

Implementation examples of the acoustic wave filters 100C and 100D are now described with reference to FIG. 16 and FIG. 17. FIG. 16 and FIG. 17 are cross-sectional views of the filter modules 1001D and 1002D according to the present exemplary embodiment. FIG. 16 and FIG. 17 are exemplary diagrams, and the acoustic wave filters 100C and 100D may be implemented with any type of various circuit implementation and circuit technologies. Thus, the description of the filter modules 1001D and 1002D provided below is not to be construed as being limiting.

The filter module 1001D includes a piezoelectric substrate 11D1 serving as an example of a first substrate. The series-arm resonators 101, 102, 104, and 105, the parallel-arm resonators 111 and 114, and wires 13, 15, 16, and 18 are disposed at the piezoelectric substrate 11D1. The wire 13 electrically connects the series-arm resonators 101 and 104 to the external connection terminal 121. The wire 18 electrically connects the series-arm resonator 105 to the external connection terminal 126. The piezoelectric substrate 11D1 is not covered with a shield.

The filter module 1002D includes a piezoelectric substrate 11D2 serving as an example of a second substrate. The series-arm resonators 103 and 106, the parallel-arm resonators 112, 113, 115, and 116, and wires 14, 15, 17, 19, and 20 are disposed at the piezoelectric substrate 11D2. The wire 19 electrically connects the series-arm resonator 106 to the external connection terminal 127. The wire 20 electrically connects the series-arm resonator 106 to the external connection terminal 128. The piezoelectric substrate 11D2 is covered with a shield 21D. In the present exemplary embodiment, the entirety of the piezoelectric substrate 11D2 is covered with the shield 21D. Instead, a part of the piezoelectric substrate 11D2 may be left without being covered with the shield 21D.

The number of series-arm resonators and the number of parallel-arm resonators included in the filter module 1001D and the filter module 1002D are not limited to the numbers of resonators illustrated in FIG. 16.

### Other Embodiments

Although an acoustic wave filter and a radio frequency module according to exemplary embodiments of the present disclosure have been described above, an acoustic wave filter and a radio frequency module according to the present disclosure are not limited to those according to the above exemplary embodiments. The present disclosure also includes other exemplary embodiments implemented by combining any components according to the above exemplary embodiments, modification examples obtained by providing, to the above exemplary embodiments, various modifications that persons having ordinary skill in the art think of within a range not departing from the gist of the present disclosure, and various devices including the above acoustic wave filter or the above radio frequency module.

For example, in a circuit configuration of each of various circuits according to the exemplary embodiments, components such as another circuit element and a wire may be inserted between a path connecting a signal path and each circuit element disclosed in the drawings.

The features of the acoustic wave filter and the radio frequency module according to each of the above exemplary embodiments are described below.
<1> An acoustic wave filter, comprising:
a first substrate having a first main surface and a second main surface opposite to each other, and having the first main surface at which a first series-arm resonator and a second series-arm resonator are disposed;
a second substrate having a third main surface facing the first main surface of the first substrate, and disposed to define a space between the third main surface and the first main surface;
a first external connection terminal connected to an antenna connection terminal;
a second external connection terminal connected to an amplifier;
a first wire that electrically connects the first external connection terminal to the first series-arm resonator;
a second wire that electrically connects the second external connection terminal to the second series-arm resonator; and
a shield disposed at the third main surface, wherein the shield at least partially overlaps the second wire without overlapping the first wire in plan view.
<2> The acoustic wave filter according to <1>,
wherein the shield does not overlap the first series-arm resonator in the plan view.
<3> The acoustic wave filter according to <1> or <2>,
wherein the shield at least partially overlaps the second series-arm resonator in the plan view.
<4> The acoustic wave filter according to any one of <1> to <3>,
wherein the shield has a mesh shape in the plan view.
<5> The acoustic wave filter according to any one of <1> to <4>,
wherein the acoustic wave filter is a surface acoustic wave filter.
<6> The acoustic wave filter according to any one of <1> to <4>,
wherein the acoustic wave filter is a bulk acoustic wave filter.
<7> The acoustic wave filter according to <6>,
wherein the first series-arm resonator includes
   a lower electrode and an upper electrode, and
   a piezoelectric member disposed between the lower electrode and the upper electrode, and
wherein the first wire is connected to the lower electrode.
<8> The acoustic wave filter according to any one of <1> to <7>,
wherein the acoustic wave filter has a pass band including a reception band of a first band, and
wherein the amplifier is a low-noise amplifier.
<9> The acoustic wave filter according to any one of <1> to <7>,
wherein the acoustic wave filter has a pass band including a transmission band of a first band, and
wherein the amplifier is a power amplifier.
<10> The acoustic wave filter according to any one of <1> to <9>, wherein the first substrate is a low temperature co-fired ceramic (LTCC) substrate.
<11> The acoustic wave filter according to any one of <1> to <9>, wherein the second substrate is a low temperature co-fired ceramic (LTCC) substrate.
<12> The acoustic wave filter according to any one of <1> to <11>, wherein the first substrate is a high temperature co-fired ceramic (HTCC) substrate.
<13> The acoustic wave filter according to any one of <1> to <11>, wherein the second substrate is a high temperature co-fired ceramic (HTCC) substrate.
<140> A radio frequency module, comprising:
a module substrate;
the acoustic wave filter according to any one of <1> to <13> disposed at the module substrate; and
an inductor disposed at the module substrate, and electrically connected to the first external connection terminal of the acoustic wave filter.
<15> The radio frequency module according to <14>, wherein the inductor is further connected to an antenna terminal.
<16> The radio frequency module according to <15>, wherein another end of the inductor is connected to ground.
<17> The radio frequency module according to any one of <14> to <16>, wherein the module substrate is a low temperature co-fired ceramic (LTCC) substrate.
<18> The radio frequency module according to any one of <14> to <16>, wherein the module substrate is a high temperature co-fired ceramic (HTCC) substrate.

The present disclosure is widely usable, as a radio frequency module disposed at a front end portion, in a communication device such as a mobile phone.

What is claimed is:

1. An acoustic wave filter, comprising:
a first substrate including a first main surface and a second main surface opposite to the first main surface, and including the first main surface at which a first series-arm resonator and a second series-arm resonator are disposed;
a second substrate including a third main surface facing the first main surface of the first substrate, and disposed to define a space between the third main surface and the first main surface;
a first external connection terminal connected to an antenna connection terminal;
a second external connection terminal connected to an amplifier;
a first wire that electrically connects the first external connection terminal to the first series-arm resonator;
a second wire that electrically connects the second external connection terminal to the second series-arm resonator; and
a shield disposed at the third main surface,
wherein the shield at least partially overlaps the second wire without overlapping the first wire in plan view.

2. The acoustic wave filter according to claim 1,
wherein the shield does not overlap the first series-arm resonator in the plan view.

3. The acoustic wave filter according to claim 1,
wherein the shield at least partially overlaps the second series-arm resonator in the plan view.

4. The acoustic wave filter according to claim 1,
wherein the shield has a mesh shape in the plan view.

5. The acoustic wave filter according to claim 1,
wherein the acoustic wave filter is a surface acoustic wave filter.

6. The acoustic wave filter according to claim 1,
wherein the acoustic wave filter is a bulk acoustic wave filter.

7. The acoustic wave filter according to claim 6,
wherein the first series-arm resonator includes
a lower electrode and an upper electrode, and
a piezoelectric member disposed between the lower electrode and the upper electrode, and
wherein the first wire is connected to the lower electrode.

8. The acoustic wave filter according to claim 1,
wherein the acoustic wave filter includes a pass band including a reception band of a first band, and
wherein the amplifier is a low-noise amplifier.

9. The acoustic wave filter according to claim 1,
wherein the acoustic wave filter includes a pass band including a transmission band of a first band, and
wherein the amplifier is a power amplifier.

10. The acoustic wave filter according to claim 1, wherein the first substrate is a low temperature co-fired ceramic (LTCC) substrate.

11. The acoustic wave filter according to claim 1, wherein the second substrate is a low temperature co-fired ceramic (LTCC) substrate.

12. The acoustic wave filter according to claim 1, wherein the first substrate is a high temperature co-fired ceramic (HTCC) substrate.

13. The acoustic wave filter according to claim 1, wherein the second substrate is a high temperature co-fired ceramic (HTCC) substrate.

14. The acoustic wave filter according to claim 2,
wherein the acoustic wave filter includes a pass band including a reception band of a first band, and
wherein the amplifier is a low-noise amplifier.

15. The acoustic wave filter according to claim 2,
wherein the acoustic wave filter includes a pass band including a transmission band of a first band, and
wherein the amplifier is a power amplifier.

16. A radio frequency module, comprising:
a module substrate;
the acoustic wave filter according to claim 1 disposed at the module substrate; and
an inductor disposed at the module substrate, and electrically connected to the first external connection terminal of the acoustic wave filter.

17. The radio frequency module according to claim 16, wherein the inductor is further connected to an antenna terminal.

18. The radio frequency module according to claim 17, wherein another end of the inductor is connected to ground.

19. The radio frequency module according to claim 16, wherein the module substrate is a low temperature co-fired ceramic (LTCC) substrate.

20. The radio frequency module according to claim 18, wherein the module substrate is a high temperature co-fired ceramic (HTCC) substrate.
